(19) United States
(12) Patent Application Publication
(10) Pub. No.: US 2014/0210008 A1
(43) Pub. Date: Jul. 31, 2014

(54) SEMICONDUCTOR DEVICE AND METHOD OF MANUFACTURING THE SAME

(71) Applicant: MITSUBISHI ELECTRIC CORPORATION, Tokyo (JP)

(72) Inventors: Yasunori ORITSUKI, Tokyo (JP); Yoichiro TARUI, Tokyo (JP)

(73) Assignee: MITSUBISHI ELECTRIC CORPORATION, Tokyo (JP)

(21) Appl. No.: 14/145,263

(22) Filed: Dec. 31, 2013

(30) Foreign Application Priority Data
Jan. 30, 2013 (JP) 2013-015252

(51) Int. Cl. H01L 27/02; H01L 29/06; H01L 21/265

(52) U.S. Cl. CPC H01L 27/0255; H01L 21/26513; H01L 29/0619
USPC 257/362; 438/237

(57) ABSTRACT

A semiconductor device includes an n-type drift layer formed on a main surface of a semiconductor substrate, a plurality of p-type well regions formed selectively in an upper layer portion of the drift layer, an n-type source region formed in a surface of the p-type well region, and a p-type contact region which is shallower than the source region formed in the surface of the p-type well region adjacent to the source region. Moreover, the semiconductor device includes an n-type additional region formed in contact with a bottom surface of the p-type well region in a position corresponding to below the contact region and deeper than the p-type well region.

### BACKGROUND OF THE INVENTION

1. Field of the Invention

The present invention relates to a semiconductor device and a method of manufacturing the same, and more particularly to a semiconductor device using a wideband gap semiconductor and a method of manufacturing the same.

2. Description of the Background Art

In a semiconductor device, particularly, a switching device such as a field effect transistor (MOSFET) having a metal/oxide/semiconductor junction structure (MOS), it is important to extract a surge current through a contact layer in generation of switching surge in order to protect a device.

For example, FIG. 1 in Japanese Patent Application Laid-Open No. 2009-16601 discloses a structure including a p-type layer in a deep position of a lower part of a body p-type layer which comes in contact with a source electrode in a p-type base region of a silicon carbide semiconductor device. By the structure, a path for a surge current is set in order of an n-type drift layer, the p-type layer, the p-type base region and the body p-type layer. When a switching surge is generated, consequently, the surge current is caused to easily flow from the p-type layer to the body p-type layer side so that the surge current flows to a surface channel layer side with difficulty.

In silicon carbide (SiC) in which an impurity is rarely diffused by heat, however, there is a problem in that great implantation energy is required for forming a deep p-type well region as in the Japanese Patent Application Laid-Open No. 2009-16601.

In the case where an n-type well region having a higher concentration than an n-type epitaxial layer is formed in a JFET region to decrease a JFET (junction FET) resistance in order to reduce a loss (an ON-state power loss) in electric conduction, that is, an ON resistance, there is a problem in that an electric field is increased in a pn junction of a p-type well and the JFET region more greatly than a lower part of a p-type contact layer, a surge current passes through the pn junction of the JFET region and flows to a source region, and a parasitic bipolar operation is thus carried out, resulting in breakdown of a device.

### SUMMARY OF THE INVENTION

It is an object to provide a semiconductor device which inhibits a parasitic bipolar operation from being carried out by a flow of a surge current to a source region, thereby preventing a device from being damaged.

A semiconductor device according to the present invention includes a semiconductor layer of a first conductivity type, a plurality of first well regions of a second conductivity type which are selectively provided in a surface of the semiconductor layer, a first semiconductor region of the first conductivity type which is selectively provided in a surface of the first well region, a second semiconductor region of the second conductivity type which is connected to the first semiconductor region in the first well region, a main electrode provided from an upper portion of the second semiconductor region to an upper portion of at least a part of the first semiconductor region, a gate insulating film provided from the upper portion of at least a part of the first semiconductor region to an upper portion of the semiconductor layer, a gate electrode provided on the gate insulating film, and a third semiconductor region of the first conductivity type which is formed in contact with a bottom surface of the first well region in a position corresponding to below the second semiconductor region and deeper than the first well region, and the third semiconductor region has a higher impurity concentration of the first conductivity type than the semiconductor layer.

According to the semiconductor device, in the case where a surge is generated, breakdown can be caused preferentially in a pn junction portion formed by the third semiconductor region and the first well region. Thus, a surge current can easily flow into the second semiconductor region without the first semiconductor region so that a parasitic bipolar operation is carried out with difficulty.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a structure of a silicon carbide MOSFET according to a first preferred embodiment of the present invention;

FIG. 2 is a plan view showing the structure of the silicon carbide MOSFET according to the first preferred embodiment of the present invention;

FIGS. 3 to 6 are sectional views showing a process for manufacturing the silicon carbide MOSFET according to the first preferred embodiment of the present invention;

FIG. 7 is a sectional view showing a structure according to a first variant of the silicon carbide MOSFET in accordance with the first preferred embodiment of the present invention;

FIG. 8 is a sectional view showing a structure according to a second variant of the silicon carbide MOSFET in accordance with the first preferred embodiment of the present invention;

FIG. 9 is a sectional view showing a structure according to a third variant of the silicon carbide MOSFET in accordance with the first preferred embodiment of the present invention;

FIG. 10 is a sectional view showing a structure according to a fourth variant of the silicon carbide MOSFET in accordance with the first preferred embodiment of the present invention;

FIG. 11 is a sectional view showing a structure according to a fifth variant of the silicon carbide MOSFET in accordance with the first preferred embodiment of the present invention;

FIG. 12 is a sectional view showing a structure according to a sixth variant of the silicon carbide MOSFET in accordance with the first preferred embodiment of the present invention;

FIG. 13 is a sectional view showing a structure according to a seventh variant of the silicon carbide MOSFET in accordance with the first preferred embodiment of the present invention;

FIG. 14 is a sectional view showing a structure of a silicon carbide MOSFET according to a second preferred embodiment of the present invention;

FIG. 15 is a sectional view showing a process for manufacturing the silicon carbide MOSFET according to the second preferred embodiment of the present invention;

FIG. 16 is a sectional view showing a structure according to a first variant of the silicon carbide MOSFET in accordance with the second preferred embodiment of the present invention;

FIG. 17 is a sectional view showing a structure according to a second variant of the silicon carbide MOSFET in accordance with the second preferred embodiment of the present invention;

FIG. 18 is a sectional view showing a structure according to a third variant of the silicon carbide MOSFET in accordance with the second preferred embodiment of the present invention;

FIG. 19 is a sectional view showing a structure according to a fourth variant of the silicon carbide MOSFET in accordance with the second preferred embodiment of the present invention;

FIG. 20 is a sectional view showing a structure according to a fifth variant of the silicon carbide MOSFET in accordance with the second preferred embodiment of the present invention;

FIG. 21 is a sectional view showing a structure according to a sixth variant of the silicon carbide MOSFET in accordance with the second preferred embodiment of the present invention;

FIG. 22 is a sectional view showing a structure according to a seventh variant of the silicon carbide MOSFET in accordance with the second preferred embodiment of the present invention;

FIG. 23 is a sectional view showing a structure according to an eighth variant of the silicon carbide MOSFET in accordance with the second preferred embodiment of the present invention; and

FIG. 24 is a sectional view showing influence by a spread of an implanted ion in ion implantation according to the seventh variant of the silicon carbide MOSFET in accordance with the second preferred embodiment of the present invention.

### DESCRIPTION OF THE PREFERRED EMBODIMENTS

<Introduction>

A term of “MOS” has been used in a metal/oxide/semiconductor junction structure since old times and is obtained by taking initial letters of Metal-Oxide-Semiconductor. However, materials of a gate insulating film and a gate electrode are improved in respect of integration, enhancement in a manufacturing process or the like in recent years, particularly, in a field effect transistor having an MOS structure (which will be hereinafter referred to as an “MOS transistor”).

For example, in the MOS transistor, a source and a drain are mainly formed in a self-aligned manner. From this viewpoint, polycrystalline silicon is employed in place of a metal as the material of the gate electrode. In respect of improvement in electrical characteristic, moreover, a material having a high dielectric constant is employed as the material of the gate insulating film. However, the material is not always restricted to oxides.

Accordingly, the term of “MOS” is not always employed with restriction to only a laminated structure of the metal/oxide/semiconductor and the restriction is not assumed in the present specification. In other words, the “MOS” is not only an abbreviation caused by the origin of the word but also has meaning including a laminated structure of an electric conductor/insulator/semiconductor widely in consideration of the common general knowledge.

### First Preferred Embodiment

<Structure of Device>

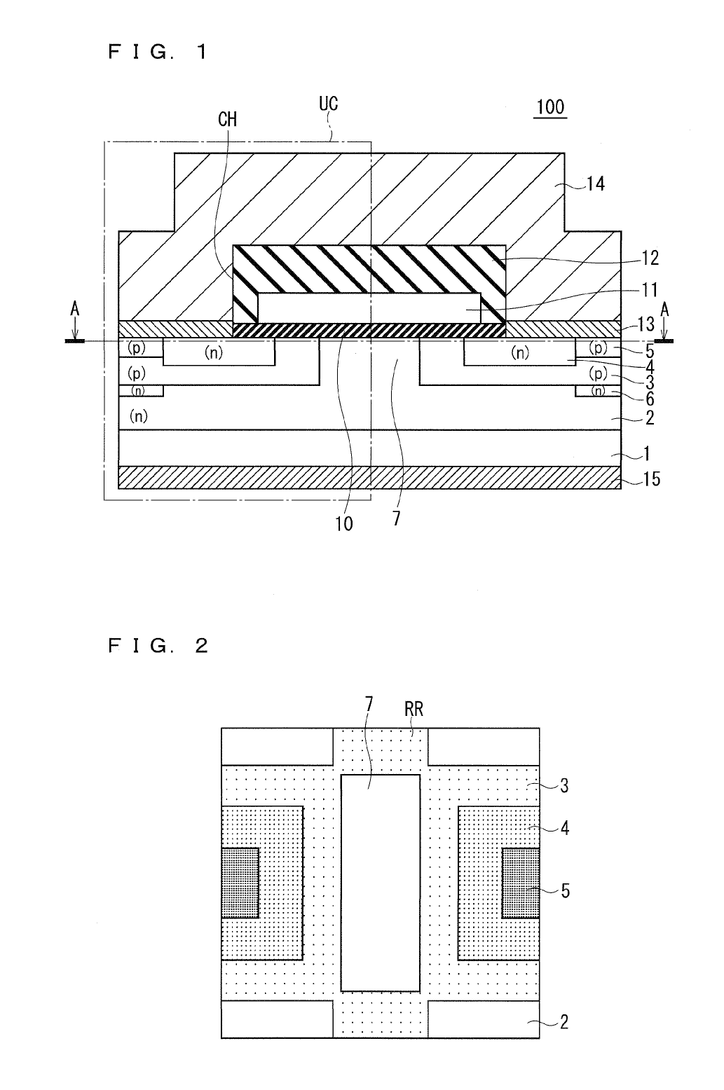

FIG. 1 is a sectional view showing a structure of a silicon carbide MOSFET 100 according to a first preferred embodiment of the present invention.

As shown in FIG. 1, the silicon carbide MOS transistor 100 includes an n-type drift layer 2 formed on a main surface of a semiconductor substrate 1 which is a silicon carbide substrate containing an n-type impurity, a plurality of p-type well regions 3 which is selectively formed on an upper layer portion of the drift layer 2, an n-type source region 4 formed in a surface of the p-type well region 3, and a p-type contact region 5 which is shallower than the source region 4 formed in the surface of the p-type well region 3 adjacently to the source region 4.

Moreover, the silicon carbide MOS transistor 100 includes an n-type additional region 6 formed in contact with a bottom surface of the p-type well region 3 in a corresponding position to a portion provided below the contact region 5, that is, a deeper position than the p-type well region 3. The additional region 6 is constituted in such a manner that a planar size is equal to that of the contact region 5.

A gate insulating film 10 is formed to cover edge portions of the source regions 4, edge portions of the p-type well regions 3 and the drift layer 2 provided between the p-type well regions 3 in the p-type well regions 3 which are adjacent to each other, and a gate electrode 11 is formed on the gate insulating film 10, respectively. An interlayer insulating film 12 is formed to cover a laminated body including the gate electrode 11 and the gate insulating film 10.

Moreover, a contact hole CH is provided such that the contact hole CH penetrates the interlayer insulating film 12, thereby reaching the contact region 5, and a silicide film 13 is formed on a bottom portion of the contact hole CH. Moreover, a source electrode 14 is formed to fill in the contact hole CH. A drain electrode 15 is formed on a main surface at a back side of the semiconductor substrate 1 (an opposite side to a main surface on which the source electrode 14 is to be provided). A single unit cell UC is formed in a region enclosed by a broken line in FIG. 1.

A planar structure obtained by an A-A line shown in FIG. 1 will be described with reference to a plan view of FIG. 2. As shown in FIG. 2, the source region 4 surrounds the contact region 5 taking an external shape of an almost square and the p-type well region 3 surrounds the source region 4 as shown in FIG. 2. The drift layer 2 provided between the adjacent p-type well regions 3 to each other serves as a JFET region 7.

In the p-type well regions 3 which are adjacent to each other, an electric field reducing region RR is provided to connect corner portions thereof. This serves to prevent an electric field from concentrating in a crossing portion of lines which diagonally connect opposed corner portions in four adjacent p-type well regions 3 to each other in the case where the plurality of p-type well regions 3 are provided in a matrix. As described above, the silicon carbide MOS transistor 100 has the additional region 6 which is formed in contact with the bottom surface of the p-type well region 3 in the corresponding position to the portion provided below the contact region 5, that is, the deeper position than the p-type well region 3.

The formation is carried out in such a manner that a centration of an n-type impurity in the additional region 6 is higher than that of an n-type impurity in the drift layer 2. Consequently, a concentration difference of a pn junction formed by the additional region 6 and the p-type well region 3 is greater than that of a pn junction formed by the drift layer 2 and the p-type well region 3. A high electric field is applied to the pn junction having a greater one of the concentration differences. Therefore, breakdown can be caused preferentially in a junction portion formed by the additional region 6 and the p-type well region 3.

When the breakdown is caused in the source region 4, a lower part of a channel region (the drain electrode 15 side) and the JFET region 7, a surge current also flows to the source region 4 provided in a current path reaching the contact region 5. In the case where the breakdown is caused only below the contact region 5, however, the current easily flows into the contact region 5 because the source region 4 is not present in the current path.

By setting the additional region 6 to be an n-type impurity region, moreover, it is possible to increase a surge resistance, and furthermore, to reduce a resistance of a built-in diode.

In the case where a body diode provided in an MOSFET is used as a free-wheel diode, moreover, a resistance value can be reduced because the impurity concentration of the additional region 6 is higher than that of the drift layer 2, and it is also possible to produce an advantage that an ON-state voltage of the free-wheel diode in electric conduction is lowered.

<Manufacturing Method>

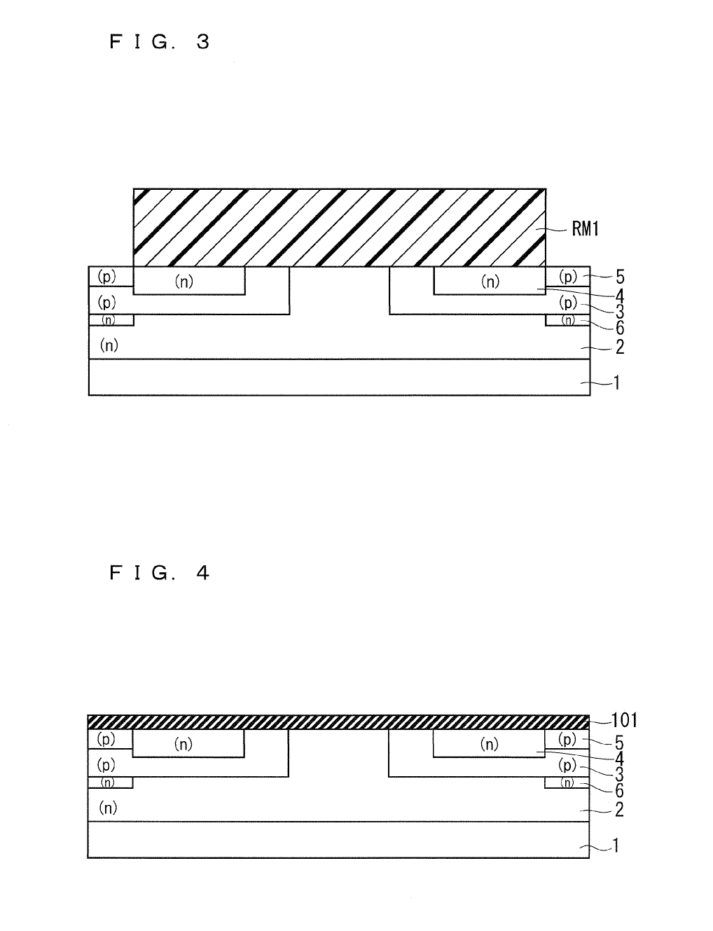

Next, a method of manufacturing the silicon carbide MOS transistor 100 will be described by using FIGS. 3 to 6 showing a manufacturing process with reference to FIG. 1.

In the following description, it is assumed that the additional region 6 is finally formed in a process for forming an impurity region, and FIG. 3 is a view showing the steps of forming the additional region 6. Since impurity regions other than the additional region 6 are implemented by the manufacturing method according to the related art, description with reference to the drawings will be omitted. First of all, a silicon carbide substrate containing an n-type impurity is prepared as the semiconductor substrate 1. As a material of the semiconductor substrate 1, it is possible to use a wideband gap semiconductor having a greater band gap than that of silicon (Si) in addition to the silicon carbide. As the other wideband gap semiconductors, it is possible to use a gallium nitride based material, an aluminum nitride based material, diamond and the like, for example.

In a switching device or a diode which is constituted by using the wideband gap semiconductor as a substrate material, a withstand voltage property is excellent and a permissible current density is also high. Therefore, a size can be reduced more greatly as compared with a silicon semiconductor device. By using the small-sized switching device or diode, it is possible to reduce a size of a semiconductor device module incorporating these devices therein.

Moreover, a heat resisting property is also excellent. Therefore, it is also possible to reduce a size of a radiation fin of a heat sink and to carry out cooling through air cooling in place of water cooling. Consequently, it is possible to reduce the size of the semiconductor device module still more.

Although a plane orientation of the semiconductor substrate 1 may be inclined by 8° or less with respect to a c-axis direction, moreover, it does not need to be inclined and the plane orientation is optional.

Then, an n-type silicon carbide epitaxial layer is formed on an upper part of the main surface of the semiconductor substrate 1 by epitaxial crystal growth and is set to be the drift layer 2. Herein, the impurity concentration of the drift layer 2 ranges from 1×10¹⁵ cm⁻³ to 5×10¹⁶ cm³, for example.

Next, a resist material is applied onto the main surface of the drift layer 2 (or a silicon oxide film is formed) and is subjected to patterning through photolithography (and etching) to form an implantation mask in which a corresponding portion to the p-type well region 3 is an opening portion. Thereafter, the implantation mask is used to carry out ion implantation of a p-type impurity, thereby forming the p-type well region 3.

Herein, the concentration of the p-type well region 3 ranges from 5×10¹⁷ cm⁻³ to 1×10¹⁹ cm³, for example.

Subsequently, a resist material is applied onto the main surface of the drift layer 2 (or a silicon oxide film is formed) and is subjected to the patterning through the photolithography (and the etching) to form an implantation mask in which a corresponding portion to the source region 4 is an opening portion. The implantation mask is used to carry out ion implantation of an n-type impurity, thereby forming the source region 4.

A depth of the source region 4 is set in such a manner that a bottom surface thereof does not exceed the bottom surface of the p-type well region 3, and has a concentration ranging from 1×10¹⁹ cm⁻³ to 1×10²⁰ cm⁻³, for example.

Next, a resist material is applied onto the main surface of the drift layer 2 (or a silicon oxide film is formed) and is subjected to the patterning through the photolithography (and the etching) to form an implantation mask RM1 in which a corresponding portion to the contact region 5 is an opening portion as shown in FIG. 3. The implantation mask RM1 is used to carry out ion implantation of the p-type impurity, thereby forming the contact region 5 in the p-type well region 3.

The contact region 5 serves to implement excellent contact of the well region 3 and the silicide film 13 and is formed to have a higher impurity concentration than that of the well region 3. The concentration of the contact region 5 ranges from 1×10²⁰ cm⁻³ to 1×10²¹ cm³, for example.

Then, the implantation mask RM1 is used again to carry out ion implantation of the n-type impurity. Consequently, the additional region 6 is formed in contact with the bottom surface of the p-type well region 3 in the corresponding position to the portion provided below the contact region 5, that is, the deeper position than the p-type well region 3. The concentration of the additional region 6 ranges from 1×10¹⁶ cm³ to 1×10¹⁸ cm³, for example.

Although the explanation has been given on the assumption that the additional region 6 is formed finally in the process for forming an impurity region, it does not need to be formed finally and a process for forming the other impurity regions is not restricted to the order described above.

In the case where the contact region 5 and the additional region 6 are formed continuously, it is possible to use a common implantation mask. Therefore, it is possible to reduce the steps of forming the implantation mask.

After the ion implanting step is ended for all of the impurity regions, activation annealing is carried out to activate the impurity subjected to the ion implantation and to recover a crystal defect formed in the ion implantation.

In a step shown in FIG. 4, next, a silicon oxide film 101 is formed over the whole main surface of the drift layer 2 by thermal oxidation or CVD (chemical vapor deposition), or execution of the CVD after the thermal oxidation, for example.

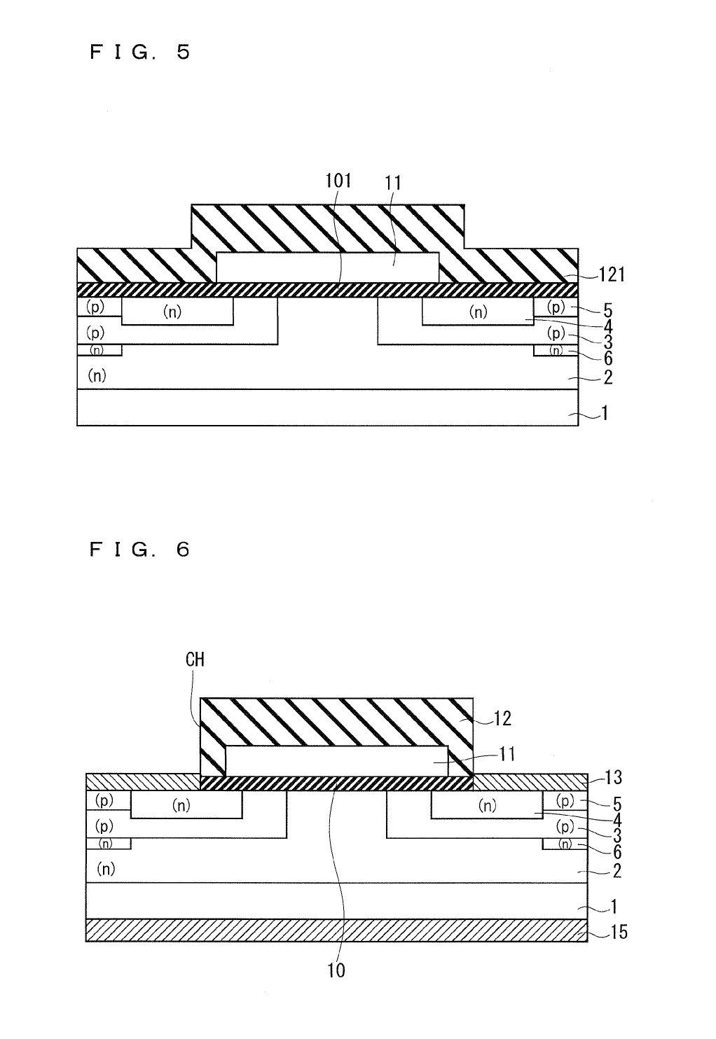

Subsequently, a polysilicon film is formed on the silicon oxide film 101 by the CVD, for example, and a resist material is applied onto a laminated film including the polysilicon film and the silicon oxide film 101 and is subjected to the patterning by the photolithography to form an etching mask in which a portion other than a corresponding portion to the gate electrode 11 is an opening portion, and the etching mask is used to etch the polysilicon film. Consequently, the gate electrode 11 is subjected to the patterning as shown in FIG. 5. In this stage, the silicon oxide film 101 is not subjected to the patterning but is left.

In a step shown in FIG. 5, then, a TEOS (tetra ethyl orthosilicate) oxide film is formed over the whole main surface of the drift layer 2 by the CVD, for example, in order to cover the gate electrode 11 and the silicon oxide film 101. Consequently, an interlayer insulating film 121 is obtained.

In a step shown in FIG. 6, next, a resist material is applied onto the interlayer insulating film 121 and is subjected to the patterning by the photolithography to form an etching mask in which corresponding portions to the contact region 5 and the upper part of the source region 4 in the vicinity thereof are opening portions. The etching mask is used to carry out the patterning over the interlayer insulating film 121 and the silicon oxide film 101 in such a manner that the contact region 5 and the upper part of the source region 4 in the vicinity thereof are exposed. Thus, the gate insulating film 10, the interlayer insulating film 12 and the contact hole CH are formed.

Thereafter, NiSi (nickel silicide) is formed on the bottom portion of the contact hole CH through a salicide step so that the silicide film 13 is obtained. An NiSi film is formed on the whole main surface at the back side of the semiconductor substrate 1 by sputtering and RTA (Rapid Thermal Annealing).

Subsequently, a titanium (Ti) film and an aluminum (Al) film are formed in this order by the sputtering so as to fill in the contact hole CH and to cover the interlayer insulating film 12. Thus, the source electrode 14 (not shown) is obtained.

Moreover, the Ni film and the Au film are formed on the NiSi film at the back side of the semiconductor substrate 1 in this order by the sputtering so that the drain electrode 15 is obtained. Consequently, there is obtained the silicon carbide MOS transistor 100 shown in FIG. 1.

A pad of a gate electrode, a field oxide film, a protective film and the like are formed, so that the silicon carbide MOS transistor 100 is completed, which is not shown in FIG. 1.

In the silicon carbide semiconductor device, P (phosphorus) or N (nitrogen) is generally used as the n-type impurity. By using light N, however, it is possible to form the additional region 6 with comparatively small implantation energy.

Although the silicon carbide MOS transistor 100 has been described above, furthermore, it is possible to obtain an IGBT (Insulated Gate Bipolar Transistor) by setting the semiconductor substrate 1 to be a p-type silicon carbide substrate or forming a p-type SiC layer on a back surface of an n-type silicon carbide substrate.

<First Variant>

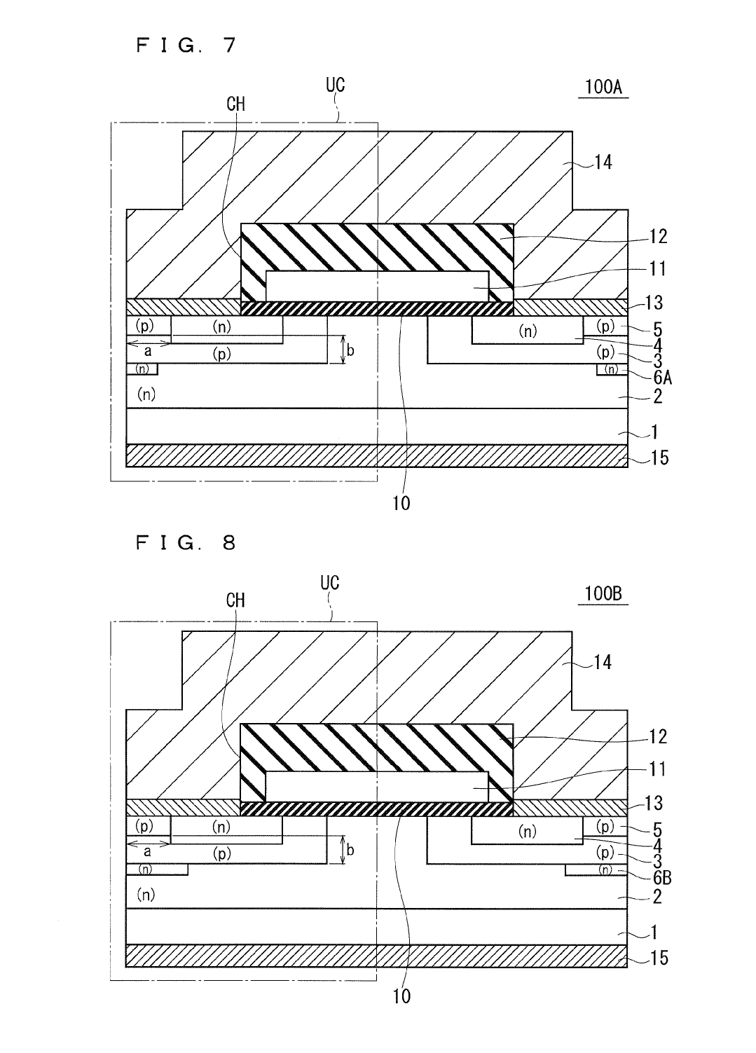

A first variant of the first preferred embodiment described above will be explained with reference to FIG. 7. FIG. 7 is a sectional view showing a structure of a silicon carbide MOS transistor 100A according to the first variant. The same structures as those of the silicon carbide MOS transistor 100 shown in FIG. 1 have the same reference numerals and repetitive description will be omitted.

As shown in FIG. 7, the silicon carbide MOS transistor 100A includes an n-type additional region 6A formed in contact with a bottom surface of a p-type well region 3 in a corresponding position to a portion provided below a contact region 5, that is, a deeper position than the p-type well region 3. The additional region 6A is constituted in such a manner that a planar size is smaller than that of the contact region 5.

By employing the structure, a surge current generated in a pn junction portion formed by the additional region 6A and the p-type well region 3 flows into a source region 4 with difficulty even if the surge current spreads. Consequently, the surge current directly flows into the contact region 5, so that a parasitic bipolar operation is carried out with difficulty.

In other words, in the case where a spreading angle of the surge current from the additional region 6A is 45 degrees (actually 45 degrees or less), for example, the current spreads in a horizontal direction (a direction along a main surface of a semiconductor device 1) by a distance which is equal to a distance b from a bottom surface of the contact region 5 to the bottom surface of the p-type well region 3. In order to perfectly prevent the surge current from flowing into the source region 4, accordingly, it is preferable to reduce the planar size of the additional region 6A by the distance b as compared with a length a in the horizontal direction of the contact region 5 in a unit cell UC. More specifically, it is preferable to form the additional region 6A in such a manner that a position of an end face of the additional region 6A is placed on an inside by the distance b from a position of the junction portion formed by the contact region 5 and the source region 4.

In order to form the additional region 6A having a smaller planar size than that of the contact region 5, an implantation mask for forming the additional region 6A is newly created separately from an implantation mask for forming the contact region 5.

<Second Variant>

Next, a second variant of the first preferred embodiment will be described with reference to FIG. 8. FIG. 8 is a sectional view showing a structure of a silicon carbide MOS transistor 100B according to the second variant. The same structures as those of the silicon carbide MOS transistor 100 shown in FIG. 1 have the same reference numerals and repetitive description will be omitted.

As shown in FIG. 8, the silicon carbide MOS transistor 100B includes an n-type additional region 6B formed in contact with a bottom surface of a p-type region 3 in a corresponding position to a portion provided below a contact region 5, that is, a deeper position than the p-type well region 3. The additional region 6B is constituted in such a manner that a planar size is larger than that of the contact region 5.

By employing the structure, an area of a pn junction portion formed by the additional region 6B and the p-type well region 3 is increased so that a larger surge current can be caused to flow and a surge resistance can be thus increased.

The planar size of the additional region 6B is determined in such a manner that the surge current flowing into a source region 4 is smaller than the surge current flowing into the contact region 5. In other words, in the case where a spreading angle of the surge current from the additional region 6B is 45 degrees (actually 45 degrees or less), for example, the current spreads in a horizontal direction (a direction along a main surface of a semiconductor substrate 1) by a distance which is equal to a distance b from a bottom surface of the contact region 5 to the bottom surface of the p-type well region 3. Accordingly, it is preferable to set the planar size of the additional region 6B to be smaller by the distance b than a double of a length a in the horizontal direction of the contact region 5 in a unit cell UC.

In order to form the additional region 6B having a larger planar size than that of the contact region 5, an implantation mask for forming the additional region 6B is newly created separately from an implantation mask for forming the contact region 5.

<Third Variant>

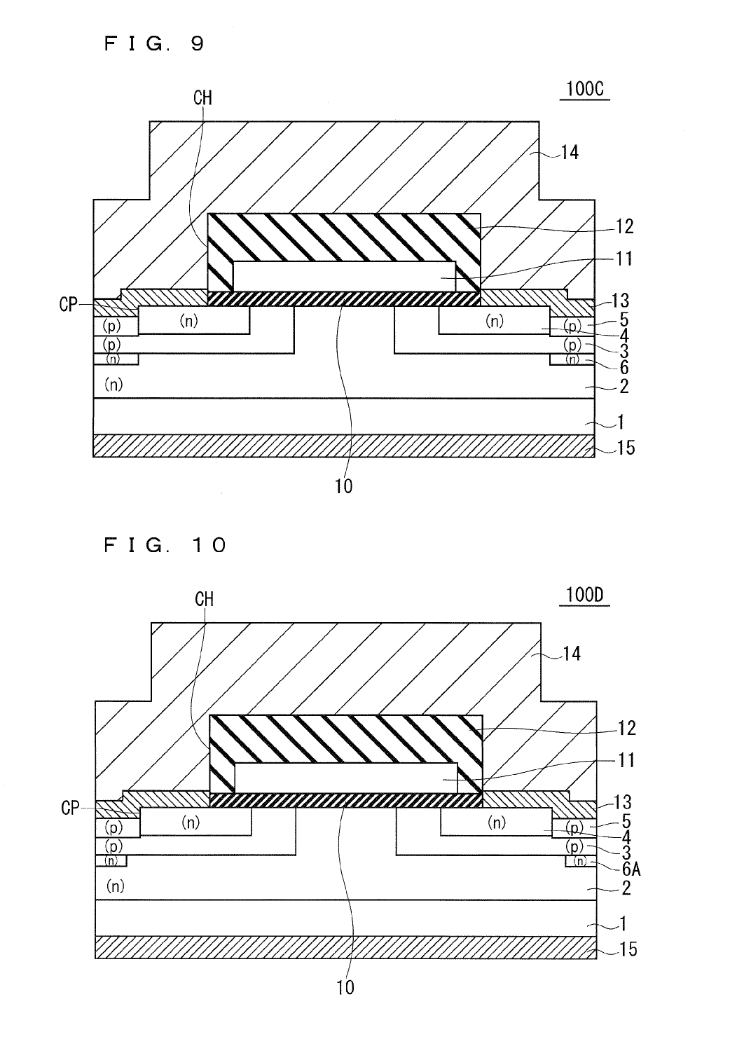

Next, a third variant of the first preferred embodiment will be described with reference to FIG. 9. FIG. 9 is a sectional view showing a structure of a silicon carbide MOS transistor 100C according to the third variant. The same structures as those of the silicon carbide MOS transistor 100 shown in FIG. 1 have the same reference numerals and repetitive description will be omitted.

As shown in FIG. 9, a silicon carbide MOS transistor 100C has such a configuration that a contact region 5 is provided in a concave portion CP and a surface thereof is retracted from a surface of a source region 4. By carrying out ion implantation for forming an additional region 6 from above the concave portion CP, accordingly, it is possible to form the additional region 6 with smaller implantation energy as compared with the formation of the additional region 6 in the silicon carbide MOS transistor 100 shown in FIG. 1.

A depth of the concave portion CP is determined in such a manner that a p-type well region 3 is left corresponding to a thickness of the contact region 5 under the contact region 5 at a minimum in order to prevent the contact region 5 from penetrating the p-type well region 3.

An etching mask for forming the concave portion CP can also be used as the implantation mask RM1 for forming the contact region 5 and the additional region 6 shown in FIG. 3. In that case, it is possible to reduce the number of the steps. If the implantation mask RM1 is constituted by a silicon oxide film, the double use can be carried out.

<Fourth Variant>

Next, a fourth variant of the first preferred embodiment will be described with reference to FIG. 10. FIG. 10 is a sectional view showing a structure of a silicon carbide MOS transistor 100D according to the fourth variant. The same structures as those of the silicon carbide MOS transistor 100 shown in FIG. 1 have the same reference numerals and repetitive description will be omitted.

As shown in FIG. 10, the silicon carbide MOS transistor 100D includes an n-type additional region 6A formed in contact with a bottom surface of a p-type well region 3 in a corresponding position to a portion provided below a contact region 5, that is, a deeper position than the p-type well region 3. The additional region 6A is constituted in such a manner that a planar size is smaller than that of the contact region 5.

By employing the structure, a surge current generated in a pn junction portion formed by the additional region 6A and the p-type well region 3 flows into a source region 4 with difficulty even if the surge current spreads. Consequently, the surge current directly flows into the contact region 5, so that a parasitic bipolar operation is carried out with difficulty.

Moreover, a silicon carbide MOS transistor 100D has such a configuration that the contact region 5 is provided in a concave portion CP and a surface thereof is retracted from a surface of the source region 4. By carrying out ion implantation for forming an additional region 6A from above the concave portion CP, accordingly, it is possible to form the additional region 6A with smaller implantation energy as compared with the formation of the additional region 6 in the silicon carbide MOS transistor 100 shown in FIG. 1.

With a structure in which the concave portion CP is provided over a whole surface of the contact region 5, an etching mask for forming the concave portion CP can also be used as the implantation mask for forming the contact region 5. Thus, it is possible to reduce the number of the steps.

With a structure in which the concave portion CP is provided in a corresponding position to a portion provided above the additional region 6A, the implantation mask RM1 for forming the additional region 6 shown in FIG. 3 can also be used, so that the number of the steps can be reduced. In any case, if the implantation mask is constituted by a silicon oxide film or a resist material, the double use can be carried out.

<Fifth Variant>

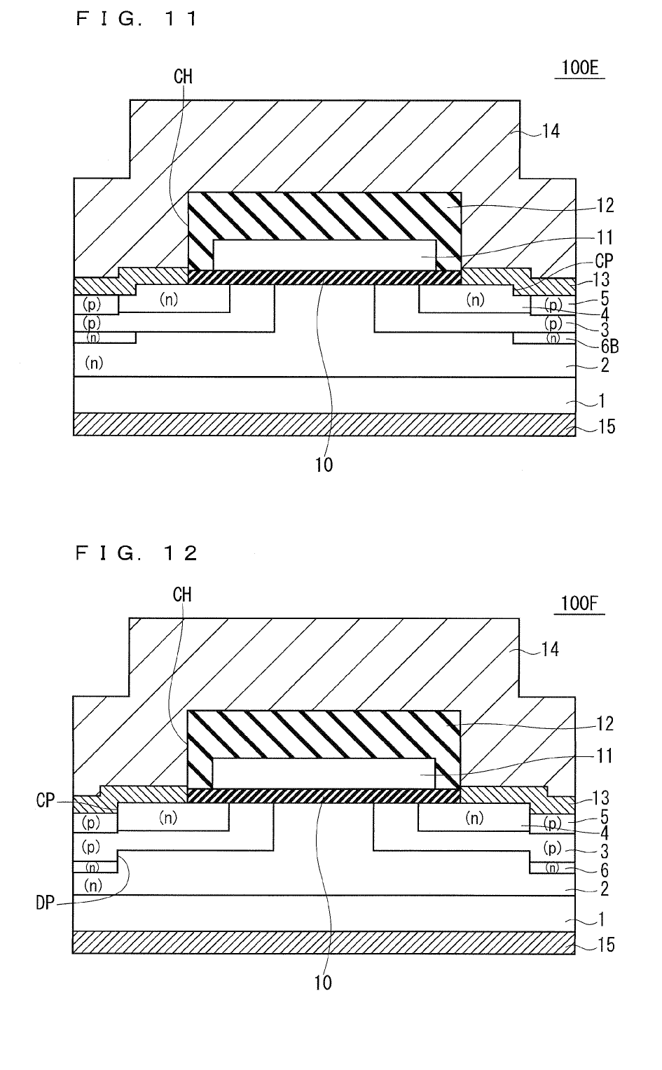

Next, a fifth variant of the first preferred embodiment will be described with reference to FIG. 11. FIG. 11 is a sectional view showing a structure of a silicon carbide MOS transistor 100E according to the fifth variant. The same structures as those of the silicon carbide MOS transistor 100 shown in FIG. 1 have the same reference numerals and repetitive description will be omitted.

As shown in FIG. 11, the silicon carbide MOS transistor 100E includes an n-type additional region 6B formed in contact with a bottom surface of a p-type well region 3 in a corresponding position to a portion provided below a contact region 5, that is, a deeper position than the p-type well region 3. The additional region 6B is constituted in such a manner that a planar size is larger than that of the contact region 5.

By employing the structure, an area of a pn junction portion formed by the additional region 6B and the p-type well region 3 is increased, so that a larger surge current can be caused to flow and a surge resistance can be thus increased.

Moreover, the silicon carbide MOS transistor 100E has a concave portion CP reaching the whole contact region 5 and an edge part of the source region 4 on a periphery thereof. By carrying out ion implantation for forming the additional region 6B from above the concave portion CP, accordingly, it is possible to form the additional region 6B with much smaller implantation energy as compared with the formation of the additional region 6 in the silicon carbide MOS transistor 100 shown in FIG. 1.

With a structure in which the concave portion CP is provided over the whole surface of the contact region 5, an etching mask for forming the concave portion CP can also be used as the implantation mask for forming the contact region 5. Thus, it is possible to reduce the number of the steps.

With a structure in which the concave portion CP is provided in a corresponding portion to a portion provided above the additional region 6B, moreover, the etching mask for forming the concave portion CP can also be used as the implantation mask for forming the additional region 6B, so that the number of the steps can be reduced. If the implantation mask is constituted by a silicon oxide film or a resist material, the double use can be carried out.

<Sixth Variant>

Next, a sixth variant of the first preferred embodiment will be described with reference to FIG. 12. FIG. 12 is a sectional view showing a structure of a silicon carbide MOS transistor 100F according to the sixth variant. The same structures as those of the silicon carbide MOS transistor 100 shown in FIG. 1 have the same reference numerals and repetitive description will be omitted.

As shown in FIG. 12, a silicon carbide MOS transistor 100F has such a configuration that a contact region 5 is provided in a concave portion CP and a surface thereof is retracted from a surface of a source region 4. A p-type well region 3 in a corresponding portion to a lower part of the concave portion CP has such a structure as to have a convex portion DP which is protruded toward a semiconductor substrate 1 side from the other portions. An additional region 6 is formed in contact with a bottom surface of the convex portion DP.

By forming the concave portion CP on a drift layer 2 and then carrying out ion implantation for forming the p-type well region 3, it is possible to obtain the p-type well region 3 having the shape described above.

By using an etching mask for forming the concave portion CP as an implantation mask, moreover, it is possible to form the contact region 5 and the additional region 6. Thus, it is possible to reduce the number of the steps.

By employing the structure described above, a pn junction portion formed by the p-type well region 3 and the additional region 6 is formed in a deeper position than a JFET region 7 so that an effective thickness of the drift layer 2 is reduced and a depletion layer easily reaches the semiconductor substrate 1. For this reason, a higher electric field is applied to the pn junction portion formed by the p-type well region 3 and the additional region 6 as compared with a pn junction portion formed by the drift layer 2 and the p-type well region 3. As a result, breakdown in the pn junction portion formed by the p-type well region 3 and the additional region 6 is apt to occur more preferentially. Consequently, a surge current flows into the contact region 5 more easily, so that a parasitic bipolar operation is carried out with difficulty.

Although there has been described the structure in which a planar size of the additional region 6 is equal to that of the contact region 5, it is also possible to provide a smaller additional region 6A than the planar size of the contact region 5 as in the silicon carbide MOS transistor 100D shown in FIG. 10.

Moreover, it is also possible to provide a larger additional region 6B than the planar size of the contact region 5 as in the silicon carbide MOS transistor 100E shown in FIG. 11. In this case, there is provided the concave portion CP reaching the whole contact region 5 and an edge portion of the source region 4 on the periphery thereof. In addition, the convex portion DP of the p-type well region 3 is also formed widely corresponding to the concave portion CP.

<Seventh Variant>

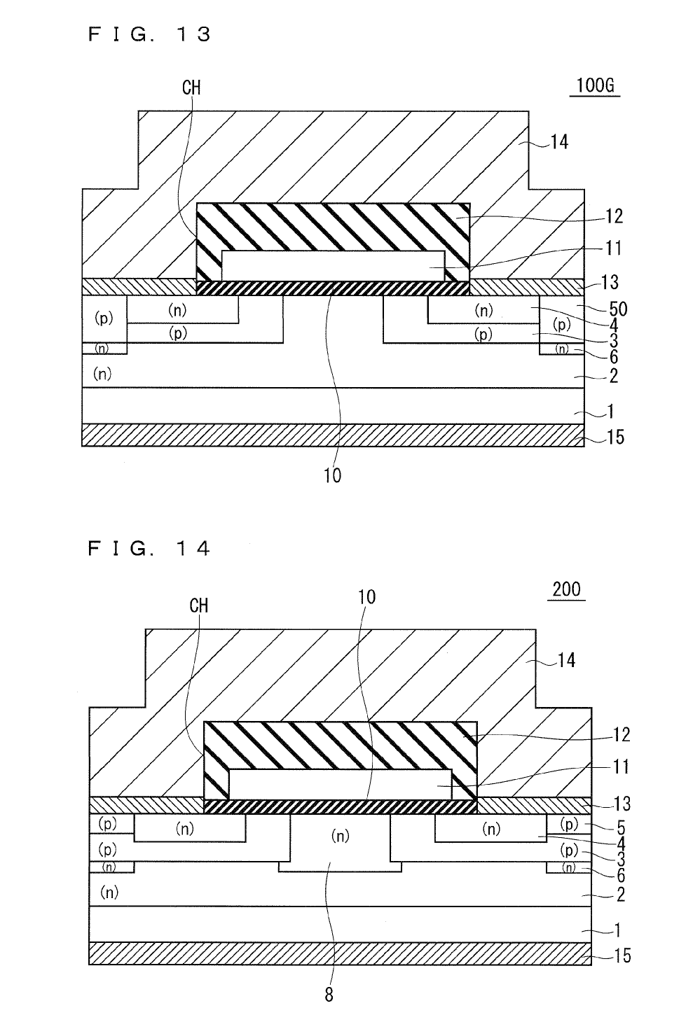

Next, a seventh variant of the first preferred embodiment will be described with reference to FIG. 13. FIG. 13 is a sectional view showing a structure of a silicon carbide MOS transistor 100G according to the seventh variant. The same structures as those of the silicon carbide MOS transistor 100 shown in FIG. 1 have the same reference numerals and repetitive description will be omitted.

As shown in FIG. 13, the silicon carbide MOS transistor 100G has such a structure that a p-type contact region 50 adjacent to a source region 4 has a depth which is equal to that of a p-type well region 3, and an additional region 6 is formed in contact with a bottom surface of the contact region 50.

In a pn junction portion formed by the contact region 50 and the additional region 6, thus, the contact region 50 has a higher concentration of a p-type impurity than that of the p-type well region 3. As compared with a pn junction portion formed by the p-type well region 3 and the additional region 6, therefore, an electric field intensity is higher. For this reason, breakdown in the pn junction portion formed by the contact region 50 and the additional region 6 is apt to occur more preferentially, and a surge current flows into the contact region 50 more easily, so that a parasitic bipolar operation is carried out with difficulty.

### Second Embodiment

<Structure of Device>

FIG. 14 is a sectional view showing a structure of a silicon carbide MOSFET 200 according to a second preferred embodiment of the present invention. The same structures as those of the silicon carbide MOSFET 100 shown in FIG. 1 have the same reference numerals and repetitive description will be omitted.

As shown in FIG. 14, the silicon carbide MOS transistor 200 includes an n-type well region 8 having an n-type impurity in a higher concentration than a drift layer 2 in a corresponding portion to a JFET region between p-type well regions 3 which are adjacent to each other.

Moreover, the silicon carbide MOS transistor 200 includes an n-type additional region 6 formed in contact with a bottom surface of the p-type well region 3 in a corresponding position to a portion provided below a contact region 5, that is, a deeper position than the p-type well region 3. The additional region 6 is constituted in such a manner that a planar size is equal to that of the contact region 5.

The formation is carried out in such a manner that a concentration of an n-type impurity of the additional region 6 is higher than that of an n-type impurity of the drift layer 2. Consequently, a concentration difference of a pn junction formed by the additional region 6 and the p-type well region 3 is higher than that of a pn junction formed by the drift layer 2 and the p-type well region 3. A high electric field is applied to the pn junction having a greater one of the concentration differences. Therefore, breakdown can be caused preferentially in the junction portion formed by the additional region 6 and the p-type well region 3.

By providing the n-type well region 8 having a higher concentration than that of the drift layer 2 in the JFET region, moreover, it is possible to reduce an electric resistance in the JFET region.

The additional region 6 is provided in order to cause the breakdown in the additional region 6 more easily in place of a corner portion of the p-type well region 3 in the structure in which the n-type well region 8 is provided. By causing the breakdown in the additional region 6, it is easy to extract a surge current into the contact region 5.

It is also possible to employ a structure in which an additional region 6A having a smaller planar size than that of the contact region 5 is provided in place of the additional region 6 as in the silicon carbide MOSFET 100A according to the first variant of the first preferred embodiment described with reference to FIG. 7.

By employing the structure, the surge current generated in a pn junction portion formed by the additional region 6A and the p-type well region 3 flows into a source region 4 with difficulty even if the surge current spreads. Consequently, the surge current directly flows into the contact region 5, so that a parasitic bipolar operation is carried out with difficulty.

It is also possible to employ a structure in which an additional region 6B having a larger planar size than that of the contact region 5 is provided in place of the additional region 6 as in the silicon carbide MOSFET 100B according to the second variant of the first preferred embodiment described with reference to FIG. 8.

By employing the structure, an area of a pn junction portion formed by the additional region 6B and the p-type well region 3 is increased, so that a larger surge current can be caused to flow and a surge resistance can be thus increased.

<Manufacturing Method>

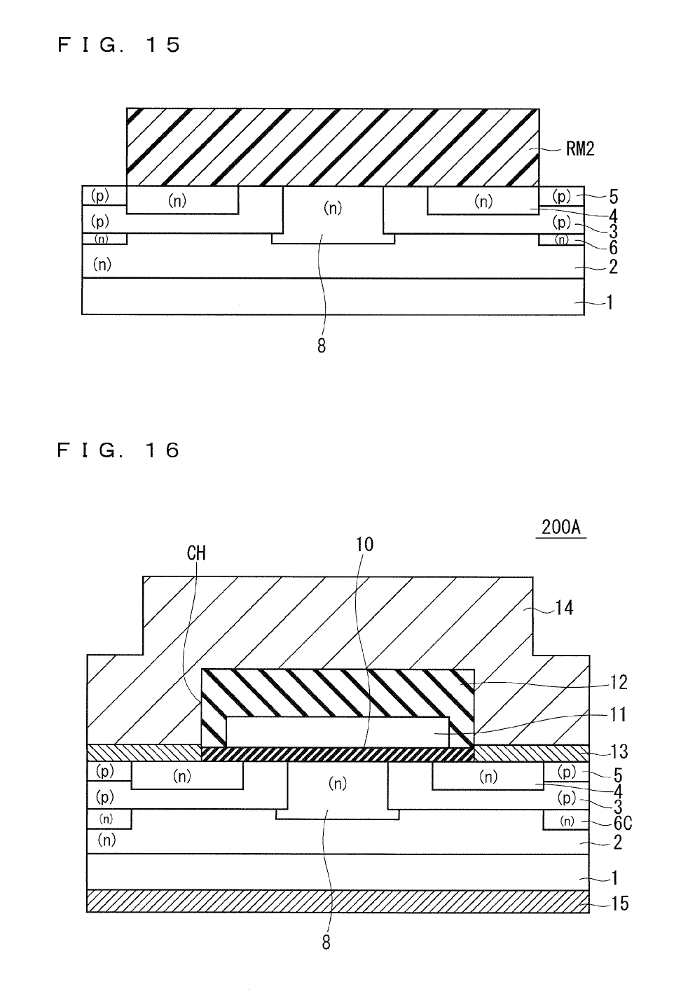

Next, a method of manufacturing the silicon carbide MOS transistor 200 will be described by using FIG. 15 showing a manufacturing process with reference to FIG. 14.

In the following description, it is assumed that the additional region 6 is finally formed in a process for forming an impurity region, and FIG. 15 is a view showing the step of forming the additional region 6. Since impurity regions other than the additional region 6 are implemented by the manufacturing method according to the related art, description using the drawings will be omitted.

First of all, there is prepared a semiconductor substrate 1 such as a silicon carbide substrate containing an n-type impurity. Then, an n-type silicon carbide epitaxial layer is formed on an upper part of a main surface of the semiconductor substrate 1 by epitaxial crystal growth so that the drift layer 2 is obtained. Herein, the impurity concentration of the drift layer 2 ranges from 1×10¹⁵ cm⁻³ to 5×10¹⁶ cm³, for example.

Next, a resist material is applied onto the main surface of the drift layer 2 (or a silicon oxide film is formed) and is subjected to patterning through photolithography (and etching) to form an implantation mask in which a corresponding portion to the p-type well region 3 is an opening portion. Thereafter, the implantation mask is used to carry out ion implantation of a p-type impurity, thereby forming the p-type well region 3.

Herein, the concentration of the p-type well region 3 ranges from 5×10¹⁷ cm⁻³ to 1×10¹⁹ cm³, for example.

Subsequently, a resist material is applied onto the main surface of the drift layer 2 (or a silicon oxide film is formed) and is subjected to the patterning through the photolithography (and the etching) to form an implantation mask in which a corresponding portion to the source region 4 is an opening portion. The implantation mask is used to carry out implantation of an n-type impurity, thereby forming the source region 4.

A depth of the source region 4 is set in such a manner that a bottom surface thereof does not exceed a bottom surface of the p-type well region 3, and a concentration thereof ranges from 1×10¹⁹ cm³ to 1×10²⁰ cm³, for example.

Next, a resist material is applied onto the main surface of the drift layer 2 (or a silicon oxide film is formed) and is subjected to the patterning through the photolithography (and the etching) to form an implantation mask in which a corresponding portion to the n-type well region 8 is an opening portion. The implantation mask is used to carry out ion implantation of the n-type impurity, thereby forming the n-type well region 8 in the surface of the drift layer 2. The concentration ranges from 1×10¹⁶ cm⁻³ to 1×10¹⁸ cm⁻³, for example.

Next, a resist material is applied onto the main surface of the drift layer 2 (or a silicon oxide film is formed) and is subjected to the patterning through the photolithography (and the etching) to form an implantation mask RM2 in which a corresponding portion to the contact region 5 is an opening portion as shown in FIG. 15. The implantation mask RM2 is used to carry out ion implantation of the p-type impurity, thereby forming the contact region 5 in the p-type well region 3.

The contact region 5 serves to implement excellent contact of the well region 3 with the silicide film 13 and is formed in such a manner as to have a higher impurity concentration than that of the well region 3. The concentration of the contact region 5 ranges from 1×10²⁰ cm⁻³ to 1×10²¹ cm³, for example.

Then, the implantation mask RM2 is used again to carry out ion implantation of the n-type impurity. Consequently, the additional region 6 is formed in contact with the bottom surface of the p-type well region 3 in the corresponding position to the portion provided below the contact region 5, that is, the deeper position than the p-type well region 3. The concentration of the additional region 6 ranges from 1×10¹⁶ cm⁻³ to 1×10¹⁸ cm³, for example.

Each of the impurity regions satisfies the concentration range, and furthermore, a concentration relationship of the drift layer 2<the n-type well region 8<the additional region 6. In the case where the n-type well region 8 and the additional region 6 are formed at the same time as will be described below, however, the impurity concentrations and implantation depths of the n-type well region 8 and the additional region 6 are equal to each other.

Although the explanation has been given on the assumption that the additional region 6 is formed finally in the process for forming an impurity region, it does not need to be formed finally and a process for forming the other impurity regions is not restricted to the order described above.

In the case where the contact region 5 and the additional region 6 are formed continuously, it is possible to use a common implantation mask. Therefore, it is possible to reduce the steps of forming the implantation mask.

In the case where the impurity concentrations and impurity depths of the additional region 6 and the n-type well region 8 are set to be equal to each other, moreover, the ion implantation of the impurity into the additional region 6 and the n-type well region 8 may be carried out by using the same implantation mask at the same time. In that case, it is impossible to use the same implantation mask as in the additional region 6 in order to form the contact region 5. For this reason, an implantation mask is formed separately.

After the ion implanting steps are ended for all of the impurity regions, activation annealing is carried out to activate the impurity subjected to the ion implantation and to recover a crystal defect formed in the ion implantation.

Then, the silicon carbide MOS transistor 200 is obtained through the steps described with reference to FIGS. 4 to 6 in the first preferred embodiment.

Although the silicon carbide MOS transistor 200 has been described above, furthermore, it is possible to obtain an IGBT by setting the semiconductor substrate 1 to be a p-type silicon carbide substrate or forming a p-type SiC layer on a back surface of an n-type silicon carbide substrate.

<First Variant>

A first variant of the second preferred embodiment described above will be explained with reference to FIG. 16. FIG. 16 is a sectional view showing a structure of a silicon carbide MOS transistor 200A according to the first variant. The same structures as those of the silicon carbide MOS transistor 200 shown in FIG. 14 have the same reference numerals and repetitive description will be omitted.

As shown in FIG. 16, the silicon carbide MOS transistor 200A includes an n-type additional region 6C formed in contact with a bottom surface of a p-type well region 3 in a corresponding position to a portion provided below a contact region 5, that is, a deeper position than the p-type well region 3. The additional region 6C is constituted in such a manner that a planar size is equal to that of the contact region 5 and has a higher impurity concentration than that of an n-type well region 8.

With the structure, a concentration difference of a pn junction portion formed by the additional region 6C and the p-type well region 3 is greater than that of a pn junction portion formed by the n-type well region 8 and the p-type well region 3. A higher electric field is applied to the pn junction portion having the greater concentration difference. Therefore, breakdown can be caused preferentially in the junction portion formed by the additional region 6C and the p-type well region 3. Consequently, a surge current can easily flow into the contact region 5.

The impurity concentration and the electric field to be applied to the pn junction portion has a proportional relationship. For example, if the impurity concentration is increased by 20%, the electric field is intensified by approximately 20%. Accordingly, it is preferable to determine an extent of the increase in the impurity concentration of the additional region 6C depending on an extent of a surge resistance.

In the case where the additional region 6C is formed so as to reach a deeper position than the n-type well region 8 as shown in FIG. 16, it is also possible to produce an advantage that an ON-state voltage of a free-wheel diode is reduced in electric conduction if a body diode provided in an MOSFET is used as the free-wheel diode. In other words, an implantation depth is increased so that a resistance of an impurity region thereof is reduced. Consequently, a resistance of a whole portion including a drift layer 2 is reduced so that the ON-state voltage of the free-wheel diode is dropped.

Moreover, an effect for dropping the ON-state voltage (reducing the resistance) of the free-wheel diode also depends on the impurity concentration of the additional region 6C. In other words, since the resistance of the impurity region is inversely proportional to the impurity concentration, it is approximately halved when the impurity concentration is doubled.

By increasing the impurity concentration and the implantation depth as in the additional region 6C, accordingly, it is possible to enhance the effect for reducing the ON-state voltage of the free-wheel diode more greatly by synergy.

An implantation mask for forming the additional region 6C can be used as an implantation mask for forming the contact region 5. In that case, it is possible to reduce the number of the steps.

<Second Variant>

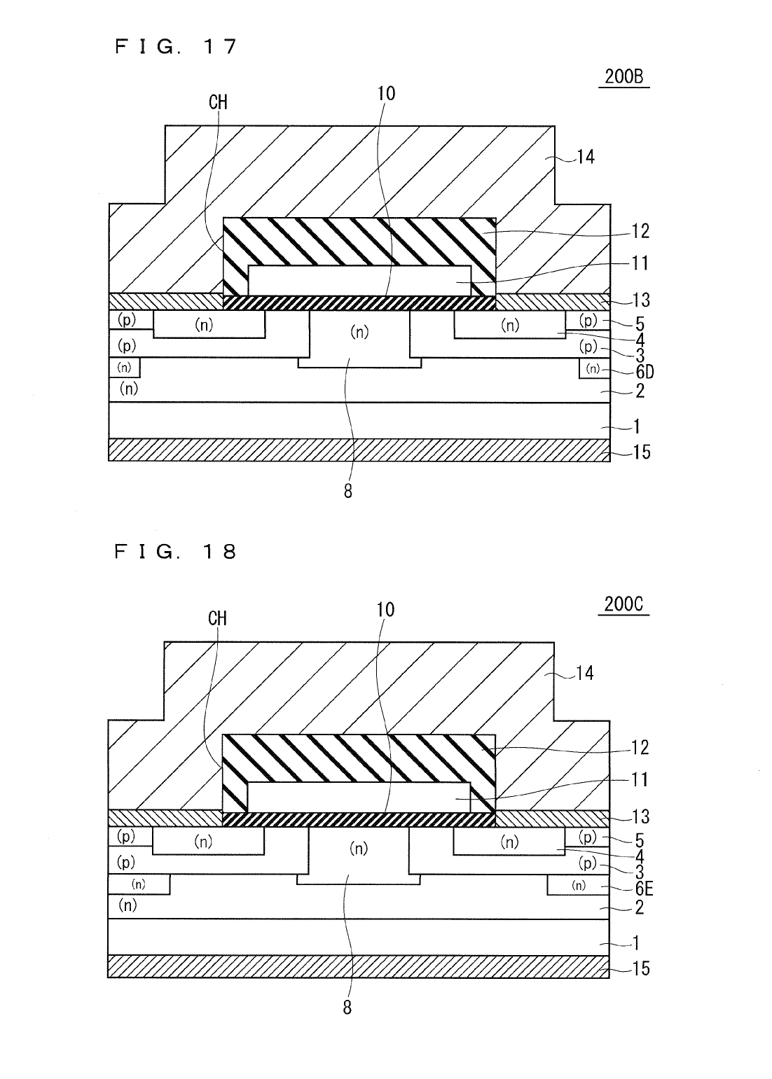

Next, a second variant of the second preferred embodiment will be described with reference to FIG. 17. FIG. 17 is a sectional view showing a structure of a silicon carbide MOS transistor 200B according to the second variant. The same structures as those of the silicon carbide MOS transistor 200 shown in FIG. 14 have the same reference numerals and repetitive description will be omitted.

As shown in FIG. 17, the silicon carbide MOS transistor 200B includes an n-type additional region 6D formed in contact with a bottom surface of a p-type well region 3 in a corresponding position to a portion provided below a contact region 5, that is, a deeper position than the p-type well region 3. The additional region 6D is constituted in such a manner that a planar size is smaller than that of the contact region 5.

By employing the structure, a surge current generated in a pn junction portion formed by the additional region 6D and the p-type well region 3 flows into a source region 4 with difficulty even if the surge current spreads. Consequently, the surge current directly flows into the contact region 5, so that a parasitic bipolar operation is carried out with difficulty.

In the case where the additional region 6D is formed so as to reach a deeper position than an n-type well region 8 as shown in FIG. 17, furthermore, it is also possible to produce an advantage that an ON-state voltage of a free-wheel diode is reduced in electric conduction if a body diode provided in an MOSFET is used as the free-wheel diode. In other words, an implantation depth is increased, so that a resistance of an impurity region thereof is reduced. Consequently, a resistance of a whole portion including a drift layer 2 is reduced, so that the ON-state voltage of the free-wheel diode is dropped.

Moreover, an effect for dropping the ON-state voltage (reducing the resistance) of the free-wheel diode also depends on the impurity concentration of the additional region 6D. In other words, since the resistance of the impurity region is inversely proportional to the impurity concentration, it is approximately halved when the impurity concentration is doubled.

By increasing the impurity concentration and the implantation depth as in the additional region 6D, accordingly, it is possible to enhance the effect for reducing the ON-state voltage of the free-wheel diode more greatly by synergy.

In the case where the implantation depth is increased, moreover, the resistance of the impurity region is reduced. Therefore, the resistance of the whole portion including the drift layer 2 is reduced. By increasing the impurity concentration and the implantation depth as in the additional region 6D, accordingly, it is possible to enhance the effect for reducing the ON-state voltage of the free-wheel diode more greatly by synergy.

In order to form the additional region 6D having a smaller planar size than that of the contact region 5, an implantation mask for forming the additional region 6D is newly created separately from an implantation mask for forming the contact region 5.

<Third Variant>

Next, a third variant of the second preferred embodiment will be described with reference to FIG. 18. FIG. 18 is a sectional view showing a structure of a silicon carbide MOS transistor 200C according to the third variant. The same structures as those of the silicon carbide MOS transistor 200 shown in FIG. 14 have the same reference numerals and repetitive description will be omitted.

As shown in FIG. 18, the silicon carbide MOS transistor 200C includes an n-type additional region 6E formed in contact with a bottom surface of a p-type well region 3 in a corresponding position to a portion provided below a contact region 5, that is, a deeper position than the p-type well region 3. The additional region 6E is constituted in such a manner that a planar size is smaller than that of the contact region 5.

By employing the structure, an area of a pn junction portion formed by the additional region 6E and the p-type well region 3 is increased, so that a larger surge current can be caused to flow and a surge resistance can be thus increased.

In the case where the additional region 6E is formed so as to reach a deeper position than an n-type well region 8 as shown in FIG. 18, it is also possible to produce an advantage that an ON-state voltage of a free-wheel diode is reduced in electric conduction if a body diode provided in an MOSFET is used as the free-wheel diode. In other words, an implantation depth is increased, so that a resistance of an impurity region thereof is reduced. Consequently, a resistance of a whole portion including a drift layer 2 is reduced, so that the ON-state voltage of the free-wheel diode is dropped.

Moreover, an effect for dropping the ON-state voltage (reducing the resistance) of the free-wheel diode also depends on the impurity concentration of the additional region 6E. In other words, since the resistance of the impurity region is inversely proportional to the impurity concentration, it is approximately halved when the impurity concentration is doubled.

By increasing the impurity concentration and the implantation depth as in the additional region 6E, accordingly, it is possible to enhance the effect for reducing the ON-state voltage of the free-wheel diode more greatly by synergy.

In the case where the implantation depth is increased, moreover, the resistance of the impurity region is reduced. Therefore, the resistance of the whole portion including the drift layer 2 is reduced. By increasing the impurity concentration and the implantation depth as in the additional region 6E, accordingly, it is possible to enhance the effect for reducing the ON-state voltage of the free-wheel diode more greatly by synergy.

In order to form the additional region 6E having a larger planar size than that of the contact region 5, an implantation mask for forming the additional region 6E is newly created separately from an implantation mask for forming the contact region 5.

<Fourth Variant>

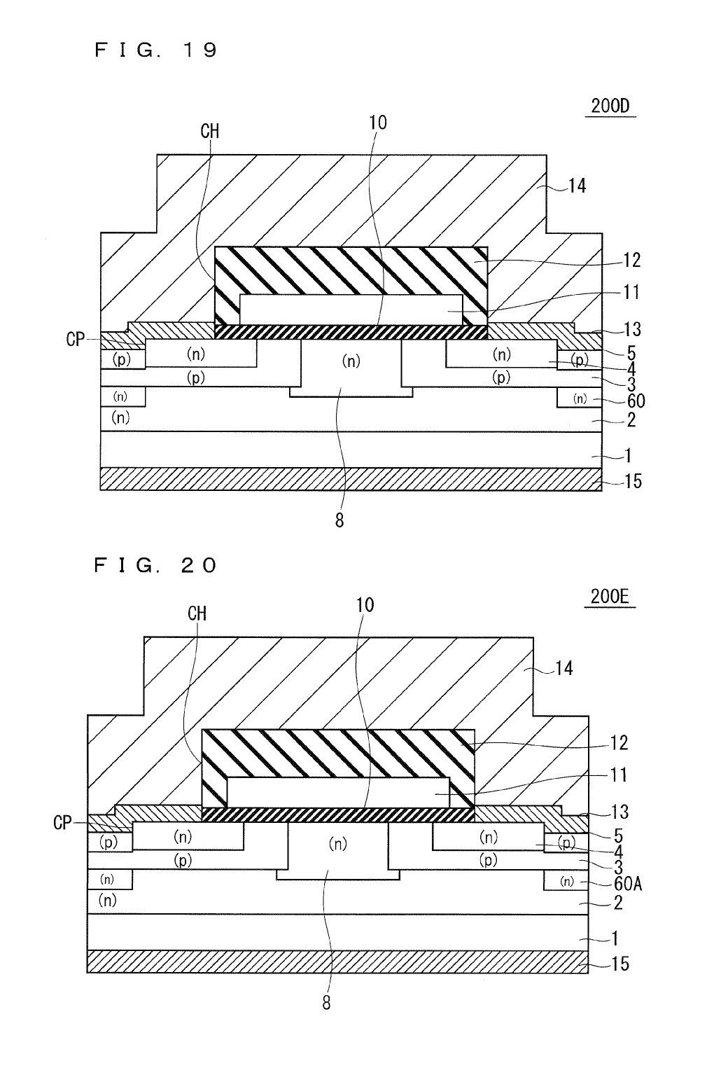

Next, a fourth variant of the second preferred embodiment will be described with reference to FIG. 19. FIG. 19 is a sectional view showing a structure of a silicon carbide MOS transistor 200D according to the fourth variant. The same structures as those of the silicon carbide MOS transistor 200 shown in FIG. 14 have the same reference numerals and repetitive description will be omitted.

As shown in FIG. 19, the silicon carbide MOS transistor 200D has such a configuration that a contact region 5 is provided in a concave portion CP and a surface thereof is retracted from a surface of a source region 4. By carrying out ion implantation for forming an additional region 60 from above the concave portion CP, accordingly, it is possible to form the additional region 60 with smaller implantation energy as compared with the formation of the additional region 6 in the silicon carbide MOS transistor 200 shown in FIG. 14.

An etching mask for forming the concave portion CP can also be used as the implantation mask for forming the contact region 5 and the additional region 60. In that case, it is possible to reduce the number of the steps. If the implantation mask is constituted by a silicon oxide film, the double use can be carried out.

In the case where the impurity concentrations of the additional region 60 and an n-type well region 8 are set to be equal to each other, moreover, the ion implantation of the impurity into the additional region 60 and the n-type well region 8 may be carried out at the same time by using the same implantation mask. In that case, the additional region 60 is formed through the concave portion CP. Therefore, the additional region 60 reaches a deeper position than the n-type well region 8 even with the same implantation energy.

As a result, in the case where a body diode provided in an MOSFET is used as a free-wheel diode, it is also possible to produce an advantage that an ON-state voltage of the free-wheel diode in electric conduction is reduced. In other words, an implantation depth is increased, so that a resistance of an impurity region thereof is reduced. Consequently, a resistance of a whole portion including a drift layer 2 is reduced so that the ON-state voltage of the free-wheel diode is dropped.

<Fifth Variant>

Next, a fifth variant of the second preferred embodiment will be described with reference to FIG. 20. FIG. 20 is a sectional view showing a structure of a silicon carbide MOS transistor 200E according to the fifth variant. The same structures as those of the silicon carbide MOS transistor 200 shown in FIG. 14 have the same reference numerals and repetitive description will be omitted.

As shown in FIG. 20, the silicon carbide MOS transistor 200E has such a configuration that the contact region 5 is provided in a concave portion CP and a surface thereof is retracted from a surface of a source region 4. By carrying out ion implantation for forming an additional region 60A from above the concave portion CP, accordingly, it is possible to form the additional region 60A with smaller implantation energy as compared with the formation of the additional region 6 in the silicon carbide MOS transistor 200 shown in FIG. 14.

An etching mask for forming the concave portion CP can also be used as an implantation mask for forming the contact region 5 and the additional region 60A. In that case, it is possible to reduce the number of the steps. Since the additional region 60A is formed separately from an n-type well region 8, moreover, an impurity concentration of the additional region 60A can be increased more greatly than that of the n-type well region 8.

With the structure, a concentration difference of a pn junction portion formed by the additional region 60A and a p-type well region 3 is greater than that of a pn junction portion formed by an n-type well region 8 and the p-type well region 3. A higher electric field is applied to the pn junction portion having the greater concentration difference. Therefore, breakdown can be caused preferentially in the junction portion formed by the additional region 60A and the p-type well region 3. Consequently, a surge current can easily flow into the contact region 5.

It is also possible to employ a structure in which an additional region 6D having a smaller planar size than that of the contact region 5 is provided in place of the additional region 60A as in the silicon carbide MOSFET 200B according to the second variant of the second preferred embodiment described with reference to FIG. 17.

By employing the structure, a surge current generated in a pn junction portion formed by the additional region 6D and the p-type well region 3 flows into a source region 4 with difficulty even if the surge current spreads. Consequently, the surge current directly flows into the contact region 5, so that a parasitic bipolar operation is carried out with difficulty.

In addition, it is also possible to employ a structure in which an additional region 6E having a larger planar size than that of the contact region 5 is provided in place of the additional region 60A as in the silicon carbide MOSFET 200C according to the third variant of the second preferred embodiment described with reference to FIG. 18.

By employing the structure, an area of a pn junction portion formed by the additional region 6E and the p-type well region 3 is increased, so that a larger surge current can be caused to flow and a surge resistance can be thus increased.

<Sixth Variant>

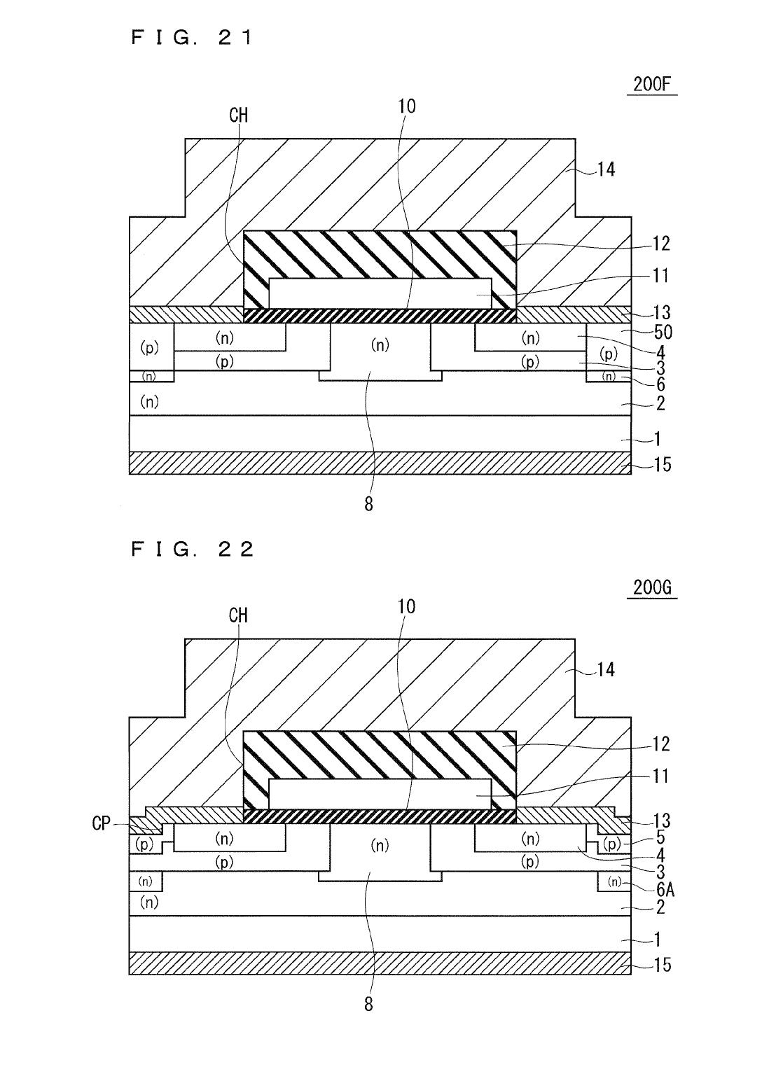

Next, a sixth variant of the second preferred embodiment will be described with reference to FIG. 21. FIG. 21 is a sectional view showing a structure of a silicon carbide MOS transistor 200F according to the sixth variant. The same structures as those of the silicon carbide MOS transistor 200 shown in FIG. 14 have the same reference numerals and repetitive description will be omitted.

As shown in FIG. 21, the silicon carbide MOS transistor 200F has such a structure that a p-type contact region 50 adjacent to a source region 4 has a depth which is equal to that of a p-type well region 3, and an additional region 6 is formed in contact with a bottom surface of the contact region 50.

In a pn junction portion formed by the contact region 50 and the additional region 6, thus, the contact region 50 has a higher concentration of a p-type impurity than the p-type well region 3. As compared with a pn junction portion formed by the p-type well region and the additional region 6, therefore, an electric field intensity is higher. For this reason, breakdown in the pn junction portion formed by the contact region 50 and the additional region 6 is caused more preferentially, and a surge current flows into the contact region 50 more easily, so that a parasitic bipolar operation is carried out with difficulty.

<Seventh Variant>

Next, a seventh variant of the second preferred embodiment will be described with reference to FIG. 22. FIG. 22 is a sectional view showing a structure of a silicon carbide MOS transistor 200G according to the seventh variant. The same structures as those of the silicon carbide MOS transistor 200 shown in FIG. 14 have the same reference numerals and repetitive description will be omitted.

As shown in FIG. 22, the silicon carbide MOS transistor 200G has a concave portion CP provided in a central part of a contact region 5. By carrying out ion implantation for forming an additional region 6A from above the concave portion CP, accordingly, it is possible to form the additional region 6A with smaller implantation energy as compared with the formation of the additional region 6 in the silicon carbide MOS transistor 200 shown in FIG. 14.

By setting the concave portion CP to have an equal size to that of the additional region 6A, it is possible to also use an etching mask for forming the concave portion CP as an implantation mask for forming the additional region 6A. In that case, it is possible to reduce the number of the steps. If the implantation mask is constituted by a silicon oxide film or a resist material, the double use can be carried out.

In the case where the impurity concentrations of the additional region 6A and an n-type well region 8 are set to be equal to each other, moreover, the ion implantation of the impurity into the additional region 6A and the n-type well region 8 may be carried out at the same time by using the same implantation mask. In that case, the additional region 6A is formed through the concave portion CP. Therefore, the additional region 6A reaches a deeper position than the n-type well region 8 even with the same implantation energy.

As a result, in the case where a body diode provided in an MOSFET is used as a free-wheel diode, it is also possible to produce an advantage that an ON-state voltage of the free-wheel diode in electric conduction is reduced. In other words, an implantation depth is increased so that a resistance of an impurity region thereof is reduced. Consequently, a resistance of a whole portion including a drift layer 2 is reduced, so that the ON-state voltage of the free-wheel diode is dropped.

As shown in FIG. 22, in the silicon carbide MOS transistor 200G, a planar size of the additional region 6A is smaller than that of the contact region 5. Therefore, a surge current generated in a pn junction portion formed by the additional region 6A and the p-type well region 3 flows into a source region 4 with difficulty even if the surge current spreads. Consequently, the surge current directly flows into the contact region 5, so that a parasitic bipolar operation is carried out with difficulty.

<Eighth Variant>

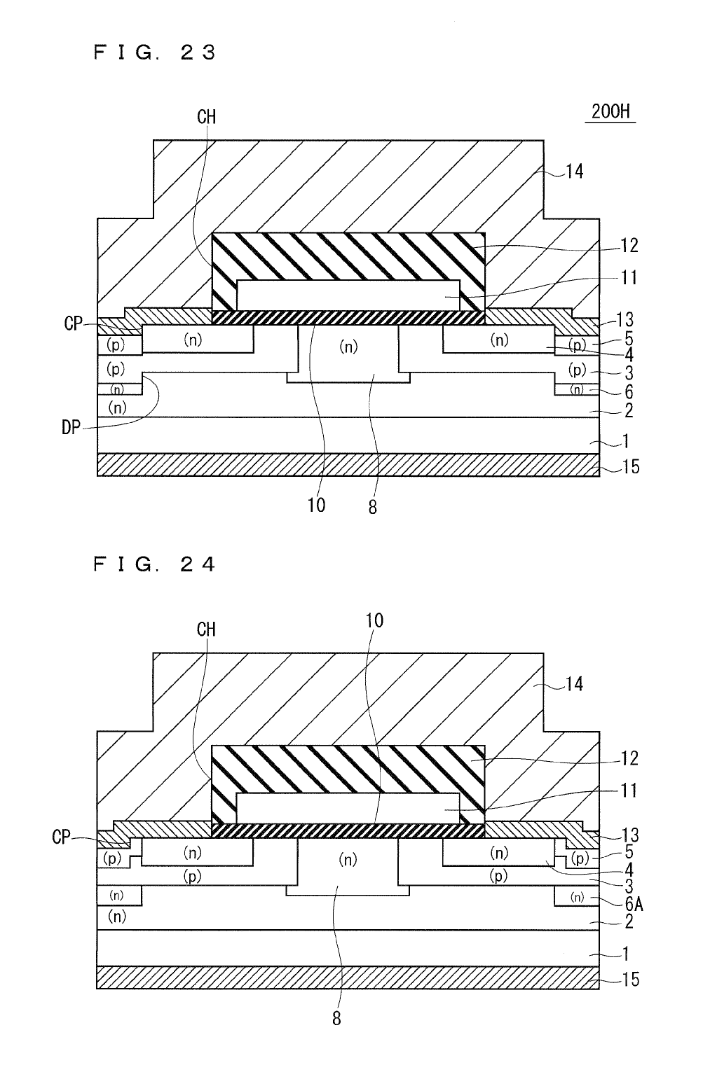

Next, an eighth variant of the second preferred embodiment will be described with reference to FIG. 23. FIG. 23 is a sectional view showing a structure of a silicon carbide MOS transistor 200H according to the eighth variant. The same structures as those of the silicon carbide MOS transistor 200 shown in FIG. 14 have the same reference numerals and repetitive description will be omitted.

As shown in FIG. 23, the silicon carbide MOS transistor 200H has such a configuration that a contact region 5 is provided in a concave portion CP and a surface thereof is retracted from a surface of a source region 4. A p-type well region 3 in a corresponding portion to a lower part of the concave portion CP has such a structure as to have a convex portion DP which is protruded toward a semiconductor substrate 1 side from the other portions. An additional region 6 is formed in contact with a bottom surface of the convex portion DP.

By forming the concave portion CP on a drift layer 2 and then carrying out ion implantation for forming the p-type well region 3, it is possible to obtain the p-type well region 3 having the shape described above. By using an etching mask for forming the concave portion CP as an implantation mask, moreover, it is possible to form the contact region 5 and the additional region 6. Thus, it is possible to reduce the number of the steps.

By employing the structure described above, a pn junction portion formed by the p-type well region 3 and the additional region 6 is formed in a deeper position than a JFET region (that is, an n-type well region 8) so that an effective thickness of the drift layer 2 is reduced and a depletion layer easily reaches the semiconductor substrate 1. For this reason, a higher electric field is applied to the pn junction portion formed by the p-type well region 3 and the additional region 6 as compared with a pn junction portion formed by the drift layer 2 and the p-type well region 3. For this reason, breakdown in the pn junction portion formed by the p-type well region 3 and the additional region 6 is caused more preferentially so that a surge current flows into the contact region 5 more easily and a parasitic bipolar operation is carried out with difficulty.

In the above description, in the case where the ion implantation or the etching is carried out by using the same mask for easy understanding, sizes (widths) of regions to be formed are expressed to be equal to each other in the drawings. For example, in the case where the etching mask for forming the concave portion CP is also used as the implantation mask for forming the additional region 6A as shown in FIG. 22, there is a possibility that the additional region 6A might take a wider configuration than the concave portion CP as shown in FIG. 24 because of the spread of the implanted ion at the time of the ion implantation.

Also in this case, however, the effects of the present invention are unchanged and the surge current flows into the contact region 5 more easily so that the parasitic bipolar operation is carried out with difficulty.

Although the description is omitted, moreover, a deep implantation region has a greater width than that of the mask also in the other preferred embodiments. However, the effects are unchanged even if the configuration is wider than the mask.

Although the n-channel MOS transistor is taken as an example in the above description, moreover, the present invention can also be applied to a p-channel MOS transistor. In the case of the p-channel MOS transistor, an additional region has a p type. By using boron (B) having a small weight as an impurity in that case, however, it is possible to reduce implantation energy.

Moreover, the impurity subjected to the ion implantation is rarely diffused by a heat treatment in the SiC. Therefore, the present invention also features that the additional region can easily be formed in a desirable size in a desirable position.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor layer of a first conductivity type;
a plurality of first well regions of a second conductivity type which are selectively provided in a surface of said semiconductor layer;
a first semiconductor region of the first conductivity type which is selectively provided in a surface of said first well region;
a second semiconductor region of the second conductivity type which is connected to said first semiconductor region in said first well region;
a main electrode provided from an upper portion of said second semiconductor region to an upper portion of at least a part of said first semiconductor region;
a gate insulating film provided from the upper portion of at least a part of said first semiconductor region to an upper portion of said semiconductor layer;
a gate electrode provided on said gate insulating film; and
a third semiconductor region of the first conductivity type which is formed in contact with a bottom surface of said first well region in a position corresponding to below said second semiconductor region and deeper than said first well region,
wherein said third semiconductor region has a higher impurity concentration of the first conductivity type than said semiconductor layer.

2. The semiconductor device according to claim 1 further comprising a second well region of the first conductivity type which is provided between said first well regions that are adjacent to each other.

3. The semiconductor device according to claim 1, wherein said third semiconductor region has a planar size which is equal to that of said second semiconductor region.

4. The semiconductor device according to claim 3, wherein said second semiconductor region is formed in a corresponding position to a concave portion provided on said semiconductor layer and at least a part of a surface thereof is retracted from a surface of said first semiconductor region.

5. The semiconductor device according to claim 4, wherein said first well region has a convex portion obtained by protrusion of a corresponding portion to a lower part of said concave portion toward said semiconductor layer side from other portions, and
said third semiconductor region is formed in contact with a bottom surface of said convex portion.

6. The semiconductor device according to claim 1, wherein said third semiconductor region is formed to have a smaller planar size than that of said second semiconductor region.

7. The semiconductor device according to claim 6, wherein said second semiconductor region is formed in a corresponding position to a concave portion provided on said semiconductor layer and at least a part of a surface thereof is retracted from a surface of said first semiconductor region.

8. The semiconductor device according to claim 7, wherein said first well region has a convex portion obtained by protrusion of a corresponding portion to a lower part of said concave portion toward said semiconductor layer side from other portions, and
said third semiconductor region is formed in contact with a bottom surface of said convex portion.

9. The semiconductor device according to claim 1, wherein said third semiconductor region is formed to have a larger planar size than that of said second semiconductor region.

10. The semiconductor device according to claim 9, wherein said second semiconductor region is formed in a corresponding position to a concave portion provided on said semiconductor layer and at least a part of a surface thereof is retracted from a surface of said first semiconductor region.

11. The semiconductor device according to claim 10, wherein said first well region has a convex portion obtained by protrusion of a corresponding portion to a lower part of said concave portion toward said semiconductor layer side from other portions, and
said third semiconductor region is formed in contact with a bottom surface of said convex portion.

12. The semiconductor device according to claim 2, wherein said third semiconductor region has an impurity implantation depth and an impurity concentration which are equal to those of said second well region.

13. The semiconductor device according to claim 2, wherein said third semiconductor region has a higher impurity concentration than that of said second well region.

14. A semiconductor device comprising:
a semiconductor layer of a first conductivity type;
a plurality of first well regions of a second conductivity type which are selectively provided in a surface of said semiconductor layer;
a first semiconductor region of the first conductivity type which is selectively provided in a surface of said first well region;
a second semiconductor region of the second conductivity type which is connected to said first semiconductor region in said first well region;
a main electrode provided from an upper portion of said second semiconductor region to an upper portion of at least a part of said first semiconductor region;
a gate insulating film provided from the upper portion of at least a part of said first semiconductor region to an upper portion of said semiconductor layer;
a gate electrode provided on said gate insulating film; and
a third semiconductor region of the first conductivity type which is formed in contact with a bottom surface of said second semiconductor region in a position corresponding to a lower part of said second semiconductor region and deeper than said first well region,
wherein said third semiconductor region has a higher impurity concentration of the first conductivity type than said semiconductor layer.

15. The semiconductor device according to claim 14 further comprising a second well region of the first conductivity type which is provided between said first well regions that are adjacent to each other.

16. A method of manufacturing a semiconductor device comprising:
a semiconductor layer of a first conductivity type;
a plurality of first well regions of a second conductivity type which are selectively provided in a surface of said semiconductor layer;
a first semiconductor region of the first conductivity type which is selectively provided in a surface of said first well region;
a second semiconductor region of the second conductivity type which is connected to said first semiconductor region in said first well region;
a main electrode provided from an upper portion of said second semiconductor region to an upper portion of at least a part of said first semiconductor region;
a gate insulating film provided from the upper portion of at least a part of said first semiconductor region to an upper portion of said semiconductor layer;
a gate electrode provided on said gate insulating film; and
a third semiconductor region of the first conductivity type which is formed in contact with a bottom surface of said first well region in a position corresponding to below said second semiconductor region and deeper than said first well region,
wherein the step of forming said third semiconductor region includes the step of carrying out ion implantation of an impurity of the first conductivity type in a higher concentration than said semiconductor layer by using an ion implantation mask for forming said second semiconductor region.

17. The method of manufacturing a semiconductor device according to claim 16, wherein said semiconductor device further includes a second well region of the first conductivity type which is provided between said first well regions that are adjacent to each other.

18. The method of manufacturing a semiconductor device according to claim 16, wherein the step of forming said second semiconductor region includes the steps of:
(a) forming said first well region in a surface of said semiconductor layer and then carrying out etching by using an etching mask in which a portion of said first well region where said second semiconductor region is to be formed is an opening portion, thereby forming a concave portion in said first well region; and
(b) carrying out ion implantation of an impurity of the second conductivity type from above said concave portion by using said etching mask as said impurity implantation mask, thereby forming said second semiconductor region.

19. The method of manufacturing a semiconductor device according to claim 16, wherein the step of forming said first well region includes the steps of:
(a) carrying out etching by using an etching mask in which a portion of said semiconductor layer where said second semiconductor region is to be formed is an opening portion, thereby forming a concave portion in said semiconductor layer; and
(b) carrying out ion implantation of an impurity of the second conductivity type by using an impurity implantation mask in which a portion where said concave portion is included and said first well region is to be formed is an opening portion, thereby forming said first well region having a convex portion obtained by protrusion of a corresponding portion to a lower part of said concave portion toward said semiconductor layer side from the other portions.

20. A method of manufacturing a semiconductor device comprising:
a semiconductor layer of a first conductivity type;
a plurality of first well regions of a second conductivity type which are selectively provided in a surface of said semiconductor layer;
a first semiconductor region of the first conductivity type which is selectively provided in a surface of said first well region;
a second semiconductor region of the second conductivity type which is connected to said first semiconductor region in said first well region;
a main electrode provided from an upper portion of said second semiconductor region to an upper portion of at least a part of said first semiconductor region;
a gate insulating film provided from the upper portion of at least a part of said first semiconductor region to an upper portion of said semiconductor layer;
a gate electrode provided on said gate insulating film; and
a third semiconductor region of the first conductivity type which is formed in contact with a bottom surface of said first well region in a position corresponding to below said second semiconductor region and deeper than said first well region, wherein the step of forming said third semiconductor region includes the steps of:
(a) carrying out etching by using an etching mask in which a portion where said third semiconductor region is to be formed is an opening portion, thereby forming a concave portion in said second semiconductor region; and
(b) carrying out ion implantation of an impurity of the first conductivity type by using said etching mask, thereby forming said third semiconductor region.

21. A method of manufacturing a semiconductor device comprising:
a semiconductor layer of a first conductivity type;
a plurality of first well regions of a second conductivity type which are selectively provided in a surface of said semiconductor layer;
a first semiconductor region of the first conductivity type which is selectively provided in a surface of said first well region;
a second semiconductor region of the second conductivity type which is connected to said first semiconductor region in said first well region;
a main electrode provided from an upper portion of said second semiconductor region to an upper portion of at least a part of said first semiconductor region;
a gate insulating film provided from the upper portion of at least a part of said first semiconductor region to an upper portion of said semiconductor layer;
a gate electrode provided on said gate insulating film;
a third semiconductor region of the first conductivity type which is formed in contact with a bottom surface of said first well region in a position corresponding to below said second semiconductor region and deeper than said first well region; and
a second well region of the first conductivity type which is provided between said first well regions that are adjacent to each other,
wherein the step of forming said second well region includes the step of carrying out ion implantation of an impurity of the first conductivity type in a higher concentration than that in said semiconductor layer by using an impurity implantation mask in which portions where said second well region is to be formed and a portion where said third semiconductor region is to be formed are opening portions, thereby forming said second well region and said third semiconductor region at the same time.
